(19) United States
(12) Patent Application Publication
(10) Pub. No.: US 2005/0068757 A1
(43) Pub. Date: Mar. 31, 2005

(54) Stress compensation layer systems for improved second level solder joint reliability

(76) Inventors: Saikumar Jayaraman, Chandler, AZ (US); Terry Sterrett, Cave Creek, AZ (US); Connie Gettinger, Chandler, AZ (US); Vijay Wakharkar, Paradise Valley, AZ (US); Agnes Padovani, Phoenix, AZ (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/676,548

(22) Filed: Sep. 30, 2003

(51) Int. Cl. H05K 1/11; H05K 1/14

(52) U.S. Cl. 361/803

(57) ABSTRACT

According to one aspect of the present invention, an electronic assembly and a method of forming an electronic assembly are provided. A semiconductor package includes a package substrate with a microelectronic die mounted to a first side and contact formations attached to a second side thereof. A stress compensation layer is formed on the first surface between the contact formations. The semiconductor package is then attached to a circuit board leaving an air space between the stress compensation layer and the circuit board. The stress compensation layer reduces stress on the contact formations and increases solder joint reliability.

### BACKGROUND OF THE INVENTION

1). Field of the Invention

This invention relates to a method of constructing an electronic assembly and to an electronic assembly, which may be made according to the method of the invention.

2). Discussion of Related Art

Integrated circuits are formed on semiconductor wafers, which are then sawed into individual semiconductor chips, also known as microelectronic dies. Each resulting die is then placed on a package substrate. The package substrate has a number of Ball Grid Array (BGA) solder ball contact formations on an opposing side, which are electrically connected to the integrated circuit through contact pads on the package substrate.

The package is then placed on a circuit board and heated to cause the solder balls to reflow, soldering the package to contact pads on the circuit board. The connections between the solder balls and the contact pads are called solder joints.

The solder joints are often brittle, and the different materials are prone to failure because of thermal stress due to differences in Coefficients of Thermal Expansion (CTEs) of the different materials and mishandling (i.e. being dropped during transportation). In general, high stress levels on the solder joints can cause them to crack, and the solder can break away from the pad. This results in the loss of the electrical connection between the chip and the circuit board and failure of the device.

### BRIEF DESCRIPTION OF THE DRAWINGS

The invention is described by way of example with reference to the accompanying drawings, wherein:

FIG. 1 is a perspective view of a semiconductor package, including a package substrate with a plurality of contact formations on bottom surface thereof;

FIG. 2 is a perspective view of the semiconductor package of FIG. 1 with the bottom surface of the package substrate facing upwards;

FIG. 3 is a perspective view of a stencil positioned over the semiconductor package of FIG. 2;

FIGS. 4-7 are cross-sectional side views of the semiconductor package and stencil of FIG. 3 illustrating the deposition of a stress compensation layer to the bottom surface of the package substrate;

FIG. 8 is a cross-sectional side view of the semiconductor package with the stress compensation layer deposited;

FIG. 9 is a perspective view of the semiconductor package with the stress compensation layer deposited;

FIG. 10 is a cross-sectional side view of the semiconductor package attached to a circuit board;

FIG. 11a is a perspective view of a substrate holder;

FIG. 11b is a perspective view the substrate holder of FIG. 11a with semiconductor packages placed thereon;

FIG. 11c is a perspective view of a matrix stencil placed over the substrate holder of FIG. 11b;

FIG. 11d is a cross-section side view of the substrate holder and matrix stencil of FIG. 11c;

FIGS. 12a and 12b are perspective views of the semiconductor package with alternative embodiments of the stress compensation layer deposited;

FIG. 13 is a perspective view of the semiconductor package illustrating an alternative method of forming the stress compensation layer;

FIGS. 14a and 14b are cross-section side views of the semiconductor package placed in a dispensing tool, which illustrate an alternative method of forming the stress compensation layer;

FIG. 14c is a top plan view of the semiconductor package further illustrating the method of FIGS. 14a and 14b;

FIGS. 15a and 15b are cross-sectional side view of the semiconductor package placed in a mold cavity, which illustrate an alternative method of forming the stress compensation layer;

FIGS. 16a-16c are cross-sectional side views of a film and a heat plate positioned over the semiconductor package, which illustrate an alternative method of forming the stress compensation layer;

FIGS. 17a and 17b are cross-sectional side views of a film positioned over the semiconductor package, which illustrates an alternative method of forming the stress compensation layer; and

FIG. 18 is a cross-section side view of the semiconductor package, with an alternative embodiment of the stress compensation layer formed thereon, attached to a circuit board.

### DETAILED DESCRIPTION OF THE INVENTION

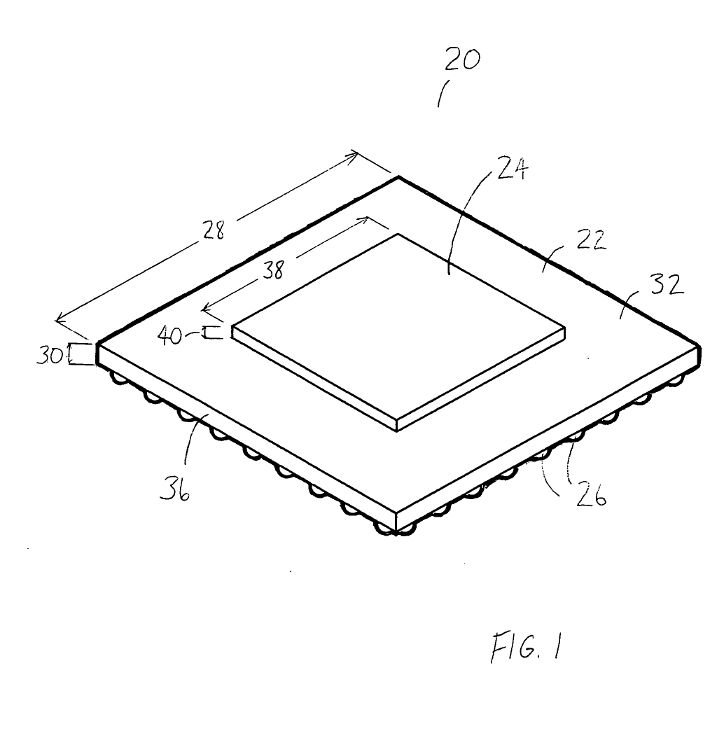

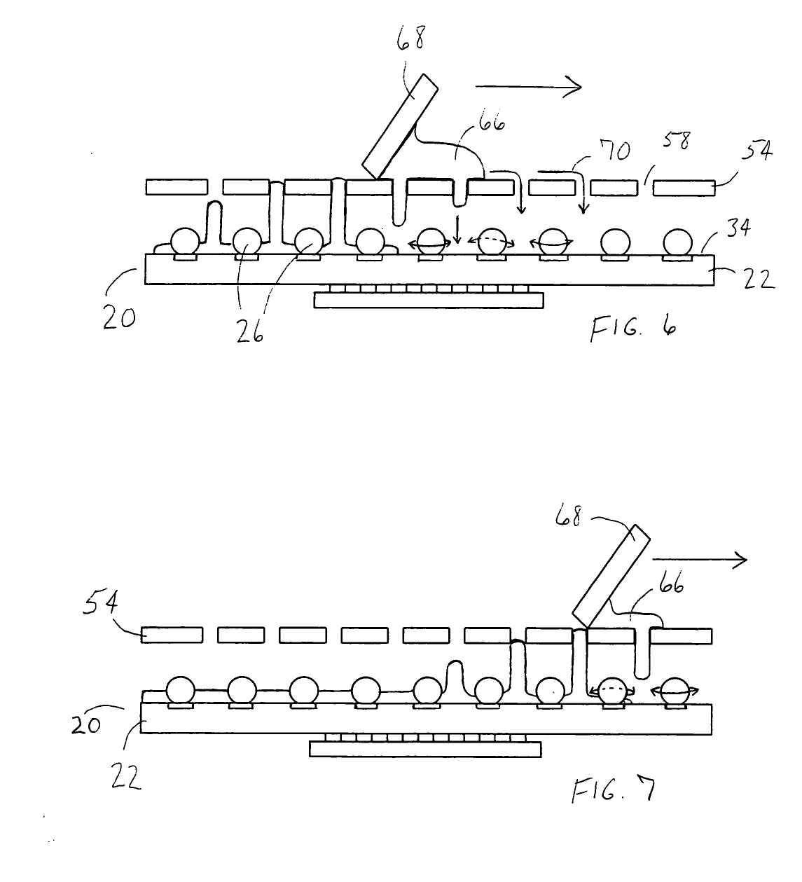

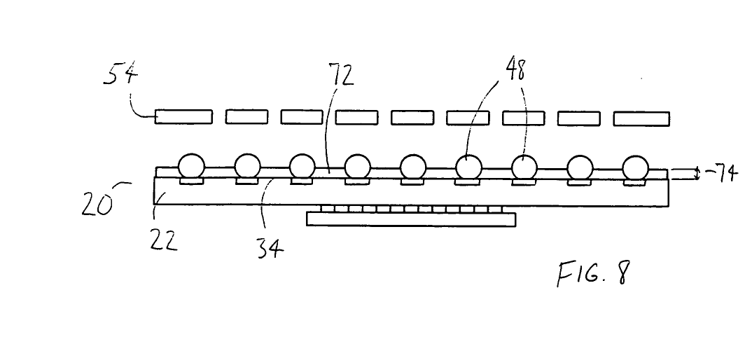

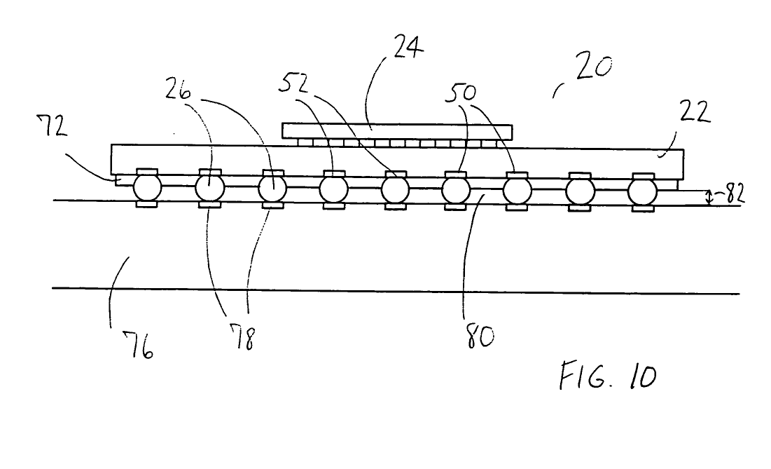

FIGS. 1 to 18 illustrate an electronic assembly and a method of forming an electronic assembly. A semiconductor package includes a package substrate with a microelectronic die mounted to a first side and contact formations attached to a second side thereof. A stress compensation layer is formed on the first surface of a semiconductor package between the contact formations to a height of approximately half the contact formations, as shown in FIG. 10. The semiconductor package is then attached to a circuit board leaving an air space between the stress compensation layer and the circuit board. The stress compensation layer reduces stress on the contact formations and increases solder joint reliability.

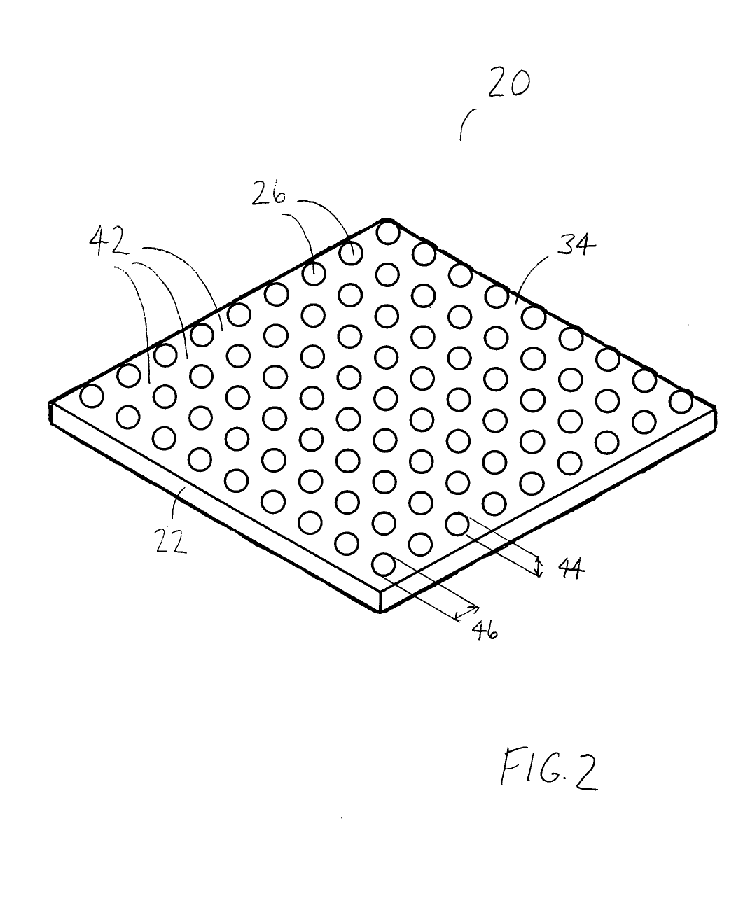

FIGS. 1 and 2 illustrate a typical semiconductor package 20, in the form of a microprocessor, which includes a package substrate 22, a microelectronic die 24, and a plurality of contact formations, such as BGA solder balls 26.

The package substrate 22 is square with, for example, side lengths 28 of 3 cm and a thickness 30 of 3 mm. The package substrate 22 has a top side with a die surface 32, a bottom side with a BGA or bottom surface 34, and an outer edge 36 and includes a plurality of alternating conducting and insulating layers therein, as is commonly understood in the art.

The microelectronic die 24 is mounted on the die surface 32 of the package substrate 22 at a central portion thereof. The microelectronic die 24 is square with, for example, side lengths 38 of 1.5 cm and a thickness 40 of 1000 microns. The microelectronic die 24 includes an integrated circuit, with multiple transistors and capacitors, formed therein and a plurality of alternating insulating and conducting layers, as is commonly understood in the art. The microelectronic die shown is in what is commonly known as a “flip-chip” configuration.

FIGS. 2 and 4 illustrate the BGA surface 34 of the package substrate 22. The BGA surface 34 includes the BGA solder balls 26 and interstitial areas 42. The BGA solder balls 26 are secured to the BGA surface 34 of the package substrate 22 and are arranged in an array of rows and columns, which covers the entire BGA surface 34. The solder balls 26 are substantially spherical, stand proud of the BGA surface 34 to heights 44 of 0.75 mm, and have diameters 46 of 0.75 mm and upper portions, or apices 48. The diameters 46 of the solder balls 26 may range, for example, between 0.2 mm and 1.5 mm. The solder balls 26 are made of solder and are attached to a plurality of contact pads 50, via solder joints 52, on the BGA surface 34 of the package substrate 22, which electrically connect the solder balls 26 to the integrated circuit within the microelectronic die 24 through the package substrate 22. The interstitial areas 42 are those portions of the BGA surface 34, arranged in rows and columns, which lie between the BGA solder balls 26.

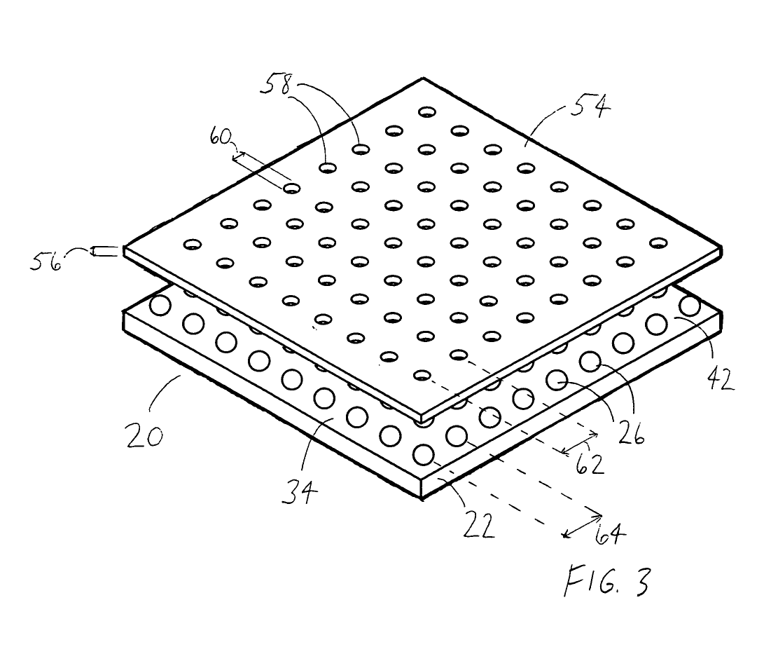

As illustrated in FIGS. 3 and 4, a stencil 54 is placed over the semiconductor package 20 with the BGA surface 34 of the package substrate 22 facing upwards. The stencil 54 is approximately the same size and shape as the package substrate 22 and has a thickness 56 of 1.5 mm. The stencil 54 includes a plurality of apertures 58, which form holes through the entire thickness 56 of the stencil 54. The apertures 58 are spread across the stencil 54 and arranged in an array of rows and columns, similar to the array of the solder balls 26. The apertures 58 are substantially circular and have diameters 60 of approximately 0.5 mm. Aperture pitch 62, or distance between the apertures 58, is the same as a pitch 64 of solder balls 26. The stencil 54 is positioned such that each aperture 58 lies directly above an interstitial area 42 of the BGA surface 34.

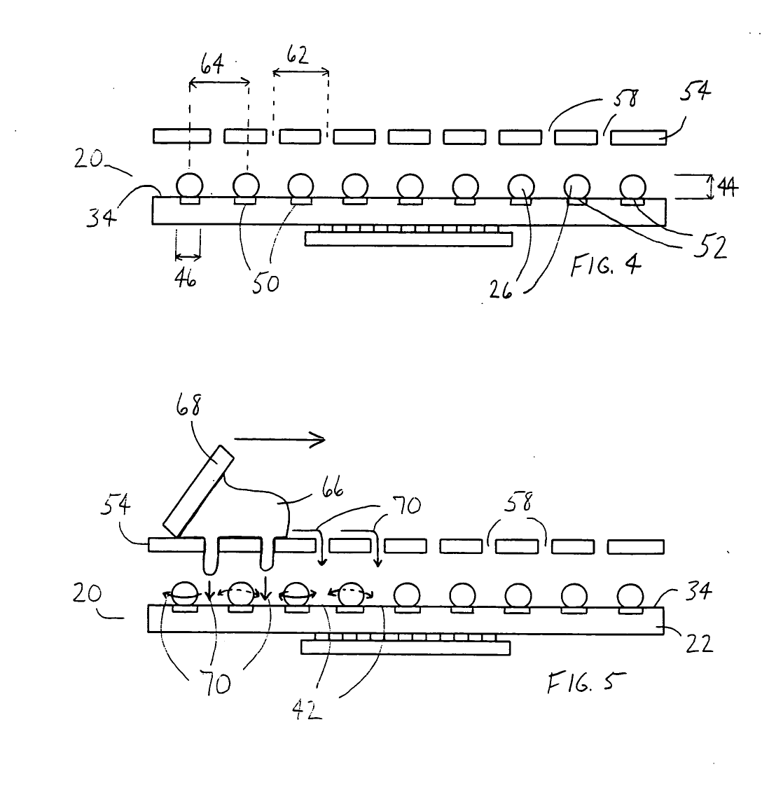

As illustrated in FIGS. 5 through 7, a mass 66 of adhesive paste or epoxy resin is placed on the stencil 54 at one end of the semiconductor package 20. The paste contains elastomer, adhesion promoters, and imidazole based catalyst for curing and has a viscosity of 6 Pascal Seconds (Pa-s) at room temperature. The semiconductor package 20 is heated to 120° C. before deposition of the paste begins.

A squeegee 68 is then lowered to contact the stencil 54 and is swept across the stencil 54 pushing the mass 66 of paste as it goes. Flow arrows 70 indicate the flow of the adhesive paste as it is pushed over the apertures 58 in the stencil 54. As the arrows 70 indicate, the adhesive paste seeps down through the apertures 58 as the squeegee 68 pushes the adhesive paste across the stencil 54. Because of the pitch 62 of the apertures 58 and the placement of the stencil 54, the adhesive paste does not fall directly onto the solder balls 26 but onto the interstitial areas 42 of the BGA surface 34. After falling onto the package substrate 22, the adhesive paste flows around the solder balls 26 through capillary action and a surface tension of the paste to cover all interstitial areas 42 and form a stress compensation, or stress relief, layer 72 on the BGA surface 34 of the package substrate 22.

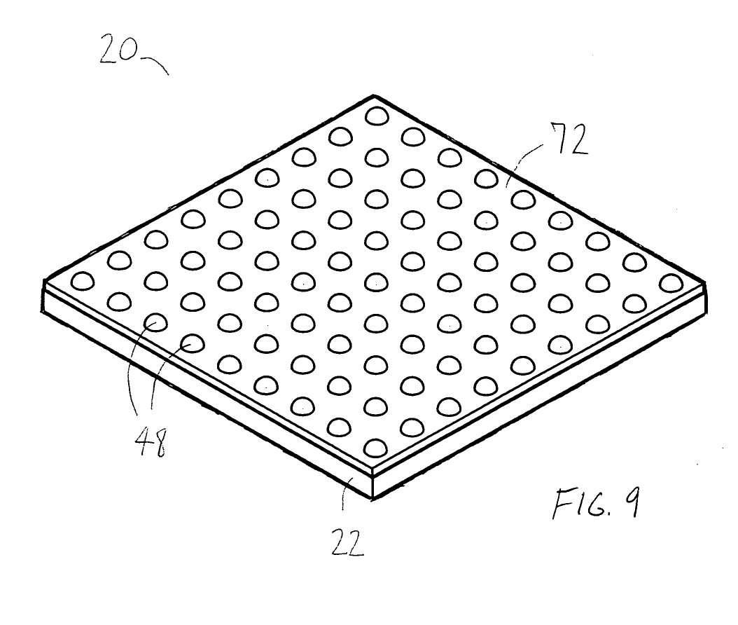

FIGS. 8 and 9 illustrate the BGA surface 34 of the package substrate 22 after the stress compensation layer 72 has been formed. As illustrated, the entire BGA surface 34 is now covered with the stress compensation layer 72, except for the upper portions 48 of the BGA solder balls 26.

Although not illustrated, the semiconductor package is then heated again to 165° C. at a heating rate of 4° C. per minute and held at that temperature for 1 hour until the paste is completely cured. After curing, the material has a glass transition temperature of 135° C., a modulus of about 3 GPa at room temperature, and a coefficient of thermal expansion of 65 parts per million (ppm) below 135° C. and 1800 ppm above 135° C.

The stress compensation layer 72 has a thickness 74, for example, of between 0.15 and 0.225 mm, or between 20% and 30% of the heights 44 of the solder balls 26 and is adjacent to a portion of the solder balls 26, which corresponds to only a portion of the height 44 of the solder balls 26.

As illustrated in FIG. 10, after the stress compensation layer 72 has been cured, by either heating or exposure to ultraviolet light and allowed to cool, the semiconductor package 20 is placed on a circuit board, such as a motherboard 76. The motherboard 76 includes a plurality of contact pads 78 each of which is located directly below one of the BGA contacts 26 of the semiconductor package 20. The contact pads 78 of the motherboard 76 electrically connect the integrated circuit within the microelectronic die 24 to the motherboard 76 and to other circuitry contained within an electronic device of which the motherboard 76 is part.

When the semiconductor package 20 is properly positioned, the motherboard 76 and package 20 are heated such that the solder balls 26 reflow and adhere the package 20 to the motherboard 76. The adhesive paste is capable of withstanding temperatures in the range of 220 and 260 degrees Celsius for short periods of time, so that the solder balls 26 can be reflowed. Such heating will not damage or melt the stress compensation layer 72 to the point of falling off the BGA surface 36. As illustrated in FIG. 10, an air space 80 is left between the stress compensation layer 72 and the motherboard 76. The air space 80 has a height 82 of, for example, 0.50 mm, which corresponds to the portion of the height 44 of the contact formations 26 not covered by the stress compensation layer 72.

In use, the motherboard 76 is placed into a computer system and power is supplied to the integrated circuit through the motherboard 76, the solder balls 26, and the package substrate 22. The die 24 sends electronic signals back into the motherboard 76, which are carried to different components of the computer system attached to the motherboard. As the integrated circuit is used, heat is generated throughout the semiconductor package 20. Due to differences in the CTEs of the materials in the package substrate 22, the solder balls 26, and the motherboard 76, the components of the entire assembly expand at different rates. This causes stress to build on the solder joints 52 between the solder balls 26 and the contact pads 50, particularly on the solder joints 52 between the package substrate 22 and the solder balls 26.

Additionally, the stress on the solder joints 52 is increased if the motherboard 76 is jolted or vibrated, such as when it is dropped or mishandled during transportation.

Because the stress compensation layer 72 is adjacent to the solder balls 26, a greater contact area is provided for the connection between the solder balls 26 and the package substrate 22. Therefore, any stress added to the solder joints 52 is partially transferred or distributed to the stress compensation layer 72 surrounding the solder balls 26, which reduces the stress on the solder joints 52.

One advantage is that because the stress on the solder joints is reduced, a more reliable connection between the semiconductor package and the circuit board is provided. Another advantage is that because of the air space between the stress compensation layer and the circuit board, if the semiconductor package needs to be removed, the solder balls can be heated to reflow again and the package removed without any of the stress compensation layer sticking to the circuit board. Another advantage is that the warpage of the package substrate is decreased because the effective thickness of the package substrate is increased.

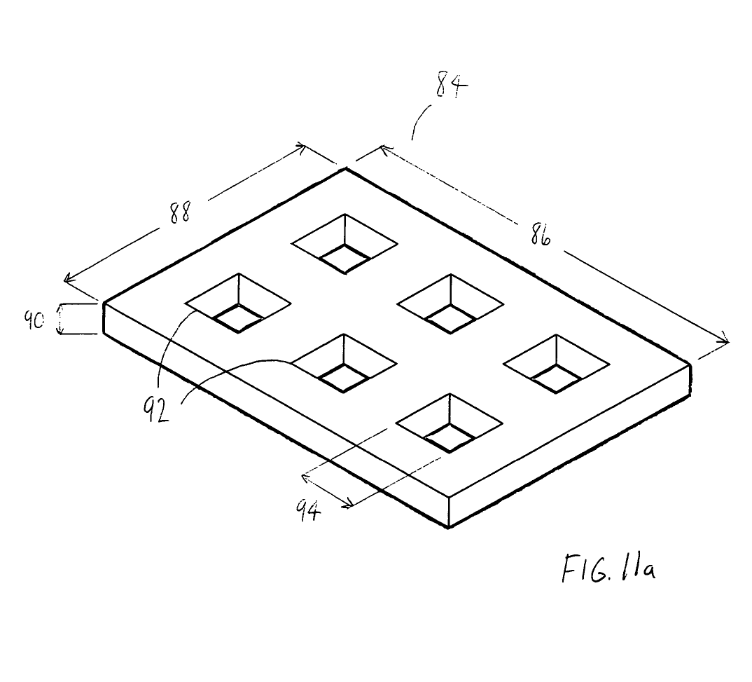

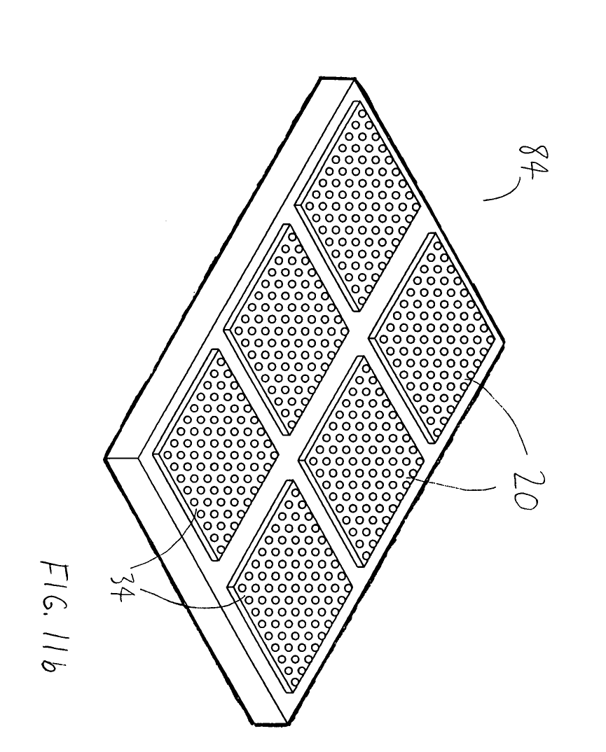

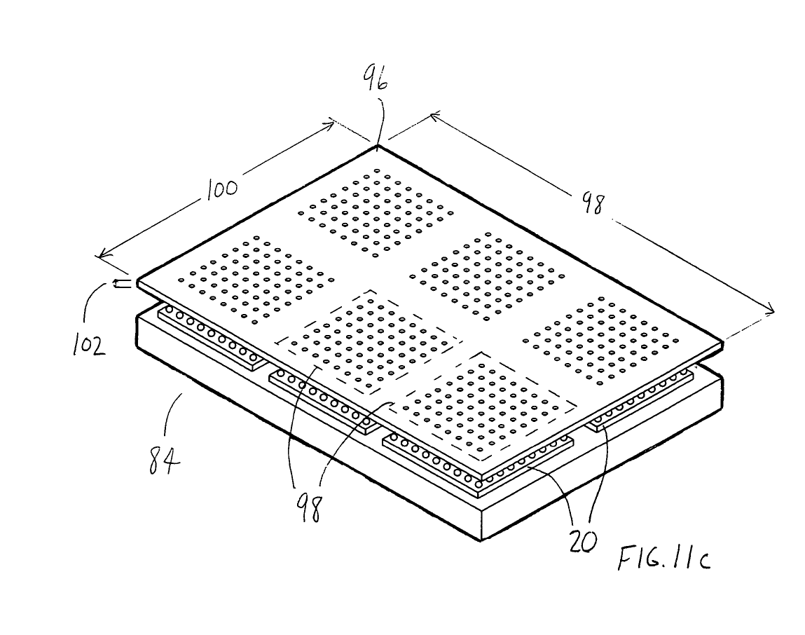

FIGS. 11a through 11d illustrate a method for forming stress compensation layers on multiple semiconductor packages.

FIG. 11a illustrates a substrate holder 84. The substrate holder 84 is rectangular with, for example, a length 86 of approximately 11 cm, a width 88 of approximately 7 cm, and a thickness 90 of approximately 1 cm. The substrate holder 84 includes, for example, six die holes 92, which extend through the thickness 90 of the substrate holder 84. Each die hole 92 is square with side lengths 94 of, for example, 1.5 cm.

As illustrated in FIGS. 11b and 11d, six semiconductor packages 20 are placed onto the substrate holder 84 so that the dice 24 on each package 20 rests in one of the die holes 92 and the BGA surfaces 34 face upwards.

As illustrated in FIG. 11c, a matrix stencil 96 is then placed over the substrate holder 84. The matrix stencil 96 is rectangular with, for example, a length 98 of 11 cm, a width 100 of 7 cm, and a thickness 102 of 0.5 cm. The matrix stencil 96 includes six arrays 98 of apertures, each one located over one of the semiconductor packages 20. Each array of apertures is similar to the array of apertures 58 on the stencil 54 shown in FIG. 3.

Referring again to FIG. 11d, a mass 104 of adhesive paste is then placed on the matrix stencil 96. A large squeegee 106 then sweeps the mass 104 of paste across the matrix stencil 96 in a similar manner as the one shown in FIGS. 5 through 7. Although only shown in cross-section, it should be understood that the mass 104 of adhesive paste and the large squeegee 106 stretch across the entire width 100 of the matrix stencil 96.

As the squeegee 106 moves the mass 104 across the matrix stencil 96, the paste seeps down through the arrays 98 and is deposited onto the interstitial areas 42 of the BGA surfaces 34 in a manner similar to the one shown in FIGS. 5 through 7.

One advantage of this method of forming the stress compensation layer is that the stress compensation layer can be formed on multiple semiconductor packages at the same time thus increasing the rate at which units are manufactured.

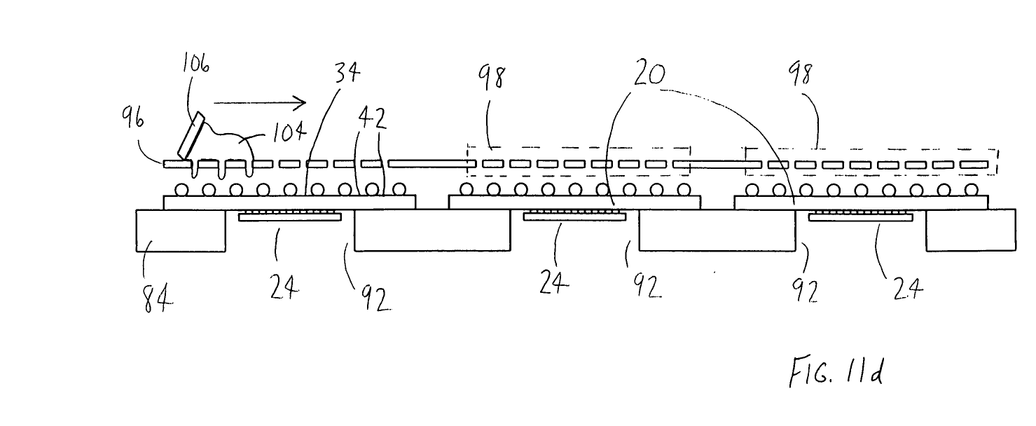

FIGS. 12a and 12b illustrate alternative embodiments of the stress compensation layer that do not cover the entire BGA surface. These embodiments may be made with methods similar to that shown in FIGS. 1 through 10 by allowing the paste to only seep through apertures located above desired locations of the stress compensation layer.

FIG. 12a illustrates the BGA surface 34 of a package substrate 22 of a semiconductor package 20 after a stress compensation layer has been formed thereon. The adhesive paste has only been deposited at the corners of the BGA surface 34. The stress compensation layer is divided into four corner sections 108, each having the shape of a right triangle. Each section has 108 a thickness of 0.37 mm and covers the interstitial portions 42 of the BGA surface 34 between seven solder balls 26 lying at the corners of the package substrate 22. The central portion, approximately shaped like a square, of the BGA surface 34 remains uncovered by any adhesive paste or the resulting stress compensation layer. The corner sections 108 may be formed by allowing the adhesive paste to seep only through apertures on the stencil located above the corners of the BGA surface 34.

FIG. 12b illustrates the BGA surface 34 of a package substrate 22 of a semiconductor package 20 after a stress compensation layer has been formed on a central portion thereof. As shown, only a square section 110 of the stress compensation layer has been deposited on a central portion of the BGA surface 34 and covers interstitial portions 42 of the BGA surface 34 between the most central nine contact formations 26 on the package substrate 22. The interstitial portions 42 of the BGA surface 34 between the contact formations at the outer regions of the BGA surface 34 remain uncovered by stress compensation layer. The square section 110 may be formed by allowing the adhesive paste to seep only through apertures on the stencil located above the central portion of the BGA surface 34.

An additional advantage of this embodiment is that the stress compensation layer can be localized. Furthermore, it should be understood that the stress compensation layer may be formed on the BGA surface in various other patterns.

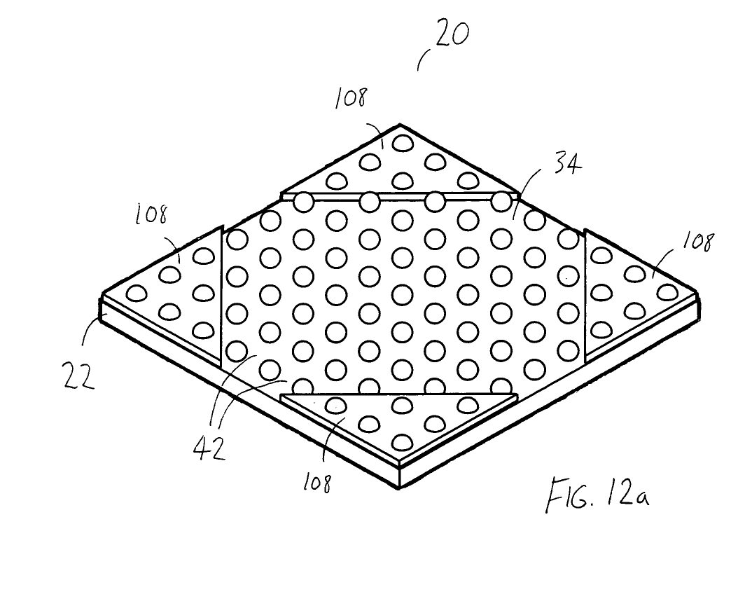

FIG. 13 illustrates another method of forming the stress compensation layer on the BGA surface of the package substrate using a syringe.

The semiconductor package 20 is placed with the BGA surface 34 facing upwards. Next, an 18-gauge syringe 112 is positioned near a corner of the BGA surface 34, above one of the interstitial areas 42. The syringe 112 then dispenses adhesive paste onto the BGA surface 34 while moving along a first row of interstitial area 42. When the syringe 112 moves past the edge 36 of the package substrate 22, the dispensing of the adhesive paste is ceased, and the syringe 112, as illustrated by arrows 114, moves to a next row of interstitial area 42. Once the syringe 112 is back over the package substrate 22, the dispensing of the adhesive paste continues, and the syringe 112 covers the next row of interstitial area 42, moving in an opposite direction from which it covered the previous row. This process is repeated until all of the interstitial area 42 is covered. The resulting semiconductor package 20 will be similar to that shown in FIG. 9 with the stress compensation layer covering the entire BGA surface. However, the paste may only be dispensed on selected portions of the BGA surface 34 if it is desired.

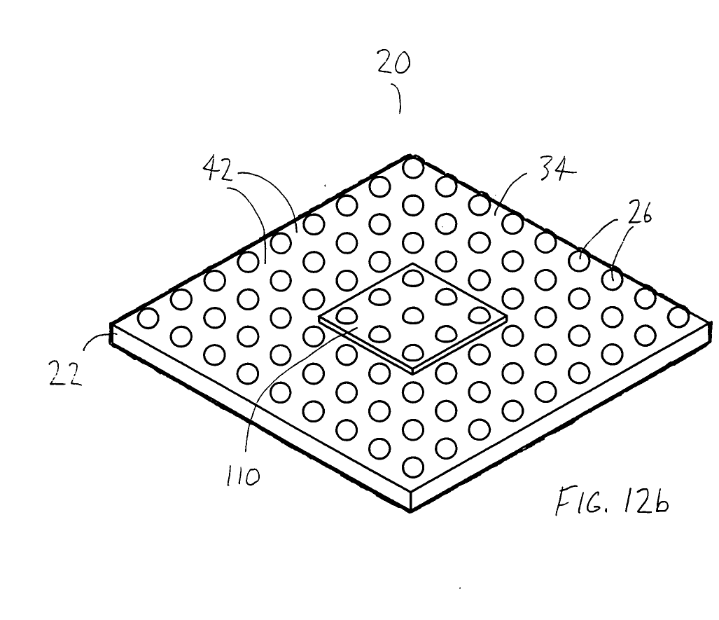

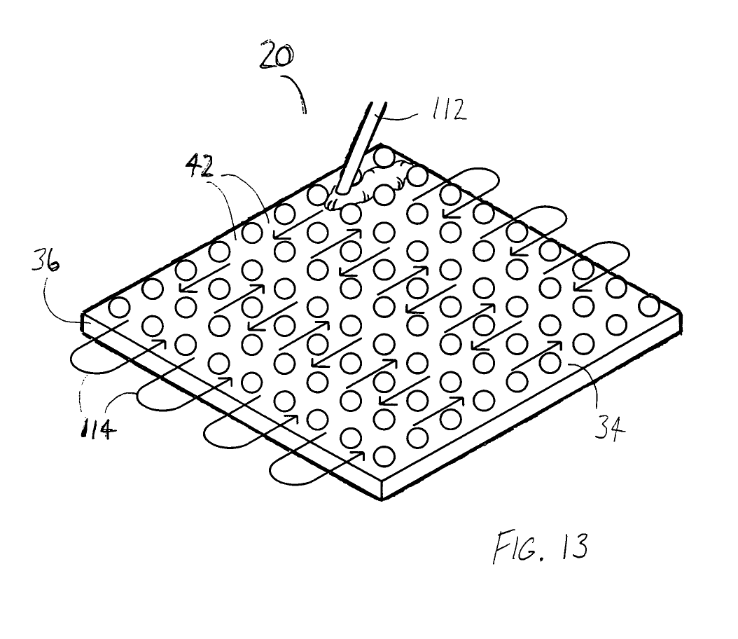

FIGS. 14a through 14c illustrate another method of forming a stress compensation layer on the BGA surface of the semiconductor package using a dispensing tool.

A dispensing tool 116 is first oriented over the semiconductor package 20. The dispensing tool 116 includes a horizontal plate 118 and a wall structure 120. Although shown only in cross section, the horizontal plate 118 is square and has a dispensing aperture 122 at a central portion thereof. The dispensing aperture 122 has a diameter 124, for example, of 0.5 cm. The wall structure 120 is attached to a periphery of a lower surface 125 of the horizontal plate 118 and extends downwards. A package cavity 126 lies between opposing portions of the wall structure 120 and has, for example, a width 128 of approximately 3 cm and a depth 130 of approximately 1 cm.

The dispensing tool 116 is placed directly over the semiconductor package 20 and lowered so that the wall structure 120 surrounds the package substrate 22 and the contact formations 26 contact the lower surface 125 of the horizontal plate 118. Although not shown, it should be understood that the wall structure surrounds and seals the edge 36 of the package substrate 22.

A dispensing needle 132 is then placed into the dispensing aperture 122, and adhesive paste is deposited into the package cavity 126. As shown in FIGS. 14b and 14c, the adhesive paste seeps onto the package substrate 22 and flows into the interstitial portions 42 of the BGA surface 34. The resulting semiconductor package 20 is similar to that illustrated in FIG. 9 with the stress compensation layer on the BGA surface 34.

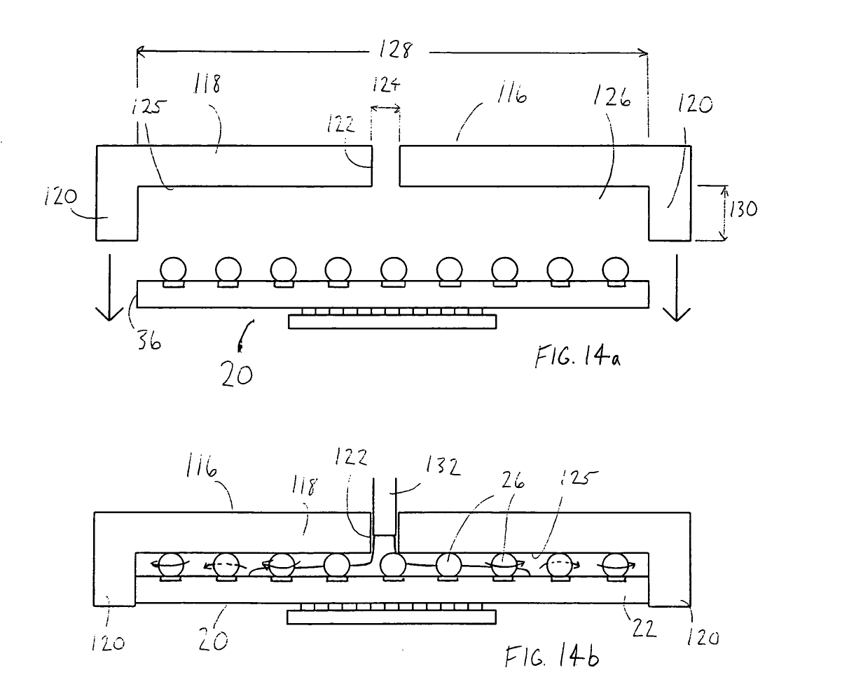

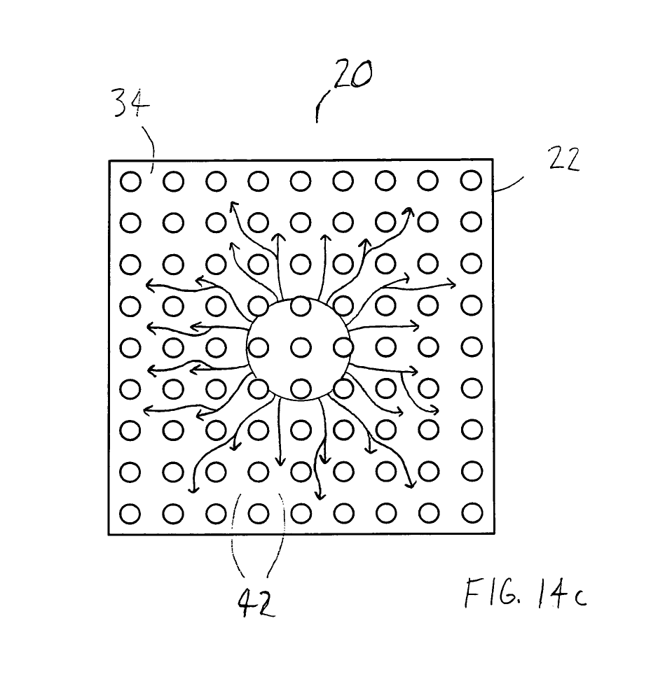

FIGS. 15a and 15b illustrate another method of forming the stress compensation layer on the BGA surface of the semiconductor package using a mold cavity.

As shown in FIG. 15a, the semiconductor package 20 is placed into a mold cavity 134. The mold cavity 134 has an upper piece 136 and a lower piece 138, which although only shown in cross-section, are substantially square.

The upper piece 136 includes a horizontal piece 140 and a two-tiered wall structure 142 attached and extending downwards from a periphery of the horizontal piece 140. A first 144 and second 146 tier of the wall structure 142 form package cavity 148 and a die cavity 150 within the package cavity 148.

Opposing inner surfaces 152 of the first tier 144 and a bottom surface 154 of the horizontal piece 140 form the die cavity 150. The die cavity 150, for example, has a width 156 of 2 cm and a depth 158 of 0.5 cm. Opposing inner surfaces 160 of the second tier 146 and a bottom surface 162 of the first tier 144 form the package cavity 148. The package cavity 148 has, for example, a width 164 of 3 cm and a depth 166 of 0.75 cm. As shown in FIGS. 15a and 15b, a gate portion 168 of the second tier 146 has slightly diminished depth.

The lower piece 138 has an upper surface 170 with a plurality of BGA depressions 172 at a central portion thereof. The BGA depressions 172 are substantially semi-spherical and have depths 174 of approximately 0.37 mm, or half the diameters 46 of the solder balls 26. Although only shown in cross-section, the BGA depressions 172 cover the upper surface 170 of the lower piece 138 and are positioned in an array of row and columns, similar to the contact formations 26.

As shown in FIG. 15a, the semiconductor package 20 is placed on the lower piece 138 of the mold cavity 134 so that the solder balls 26 rest within the BGA depressions 172. An air space 176 with a height 178 of approximately 0.37 mm lies between the upper surface 170 of the lower piece 138 and the BGA surface 34 of the package substrate 22.

The upper piece 136 is then lowered over the semiconductor package 20. The die cavity 150 surrounds the microelectronic die 24, and the package cavity 148 surrounds the package substrate 22. The opposing inner surfaces 160 of the second tier 146 are adjacent to the outer edge 36 of the package substrate 22. Except for the gate portion 168, the entire second tier 146 comes into contact with the upper surface 170 of the lower piece 138 and surrounds the semiconductor package 20. A gate 180 is formed between the upper surface 170 of the lower piece 138 and the gate portion 168 of the second tier 146. The gate 180 is a passageway with a height 182 of approximately 0.37 mm.

As illustrated in FIG. 15b, adhesive paste is then injected through the gate 180 and into the air space 176. The paste covers the interstitial areas 42 and adheres to BGA surface 34. The resulting semiconductor package 20 is similar to the one shown in FIG. 9 with the stress compensation layer on the BGA surface 34.

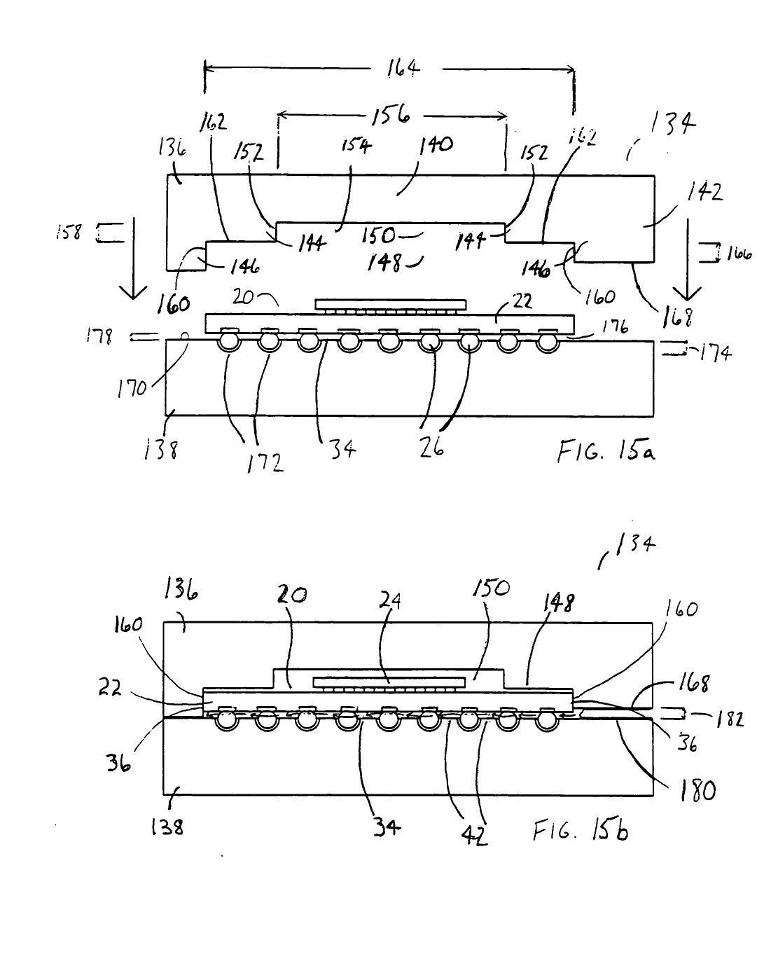

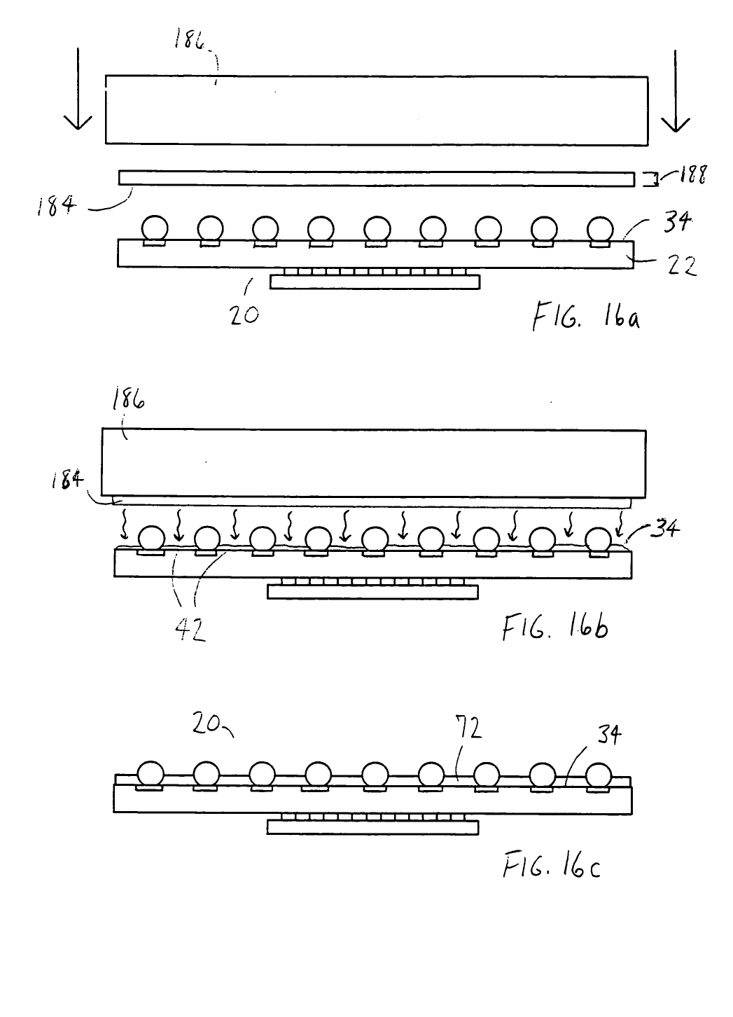

FIGS. 16a through 16c illustrate another method of forming the stress compensation layer on the BGA surface of semiconductor package using an extruded film.

As shown in FIG. 16a, a film 184 of adhesive paste is placed over the BGA surface 34 of the package substrate 22, and a heat plate 186 is placed over the film 184. The film 184 has a thickness 188 of approximately 0.37 mm.

The heat plate 186 is then lowered to contact the film 184. As shown in FIG. 16b, when the heat plate 186 contacts the film 184, the film 184 softens, forming a melt, and is deposited onto the interstitial areas 42 of the BGA surface 34. As shown in FIG. 15c, when the entire film 184 has melted, the stress compensation layer 72 is formed on the BGA surface 34. The resulting semiconductor package 20 is similar to the one in FIG. 9 with the stress compensation layer on the BGA surface 34.

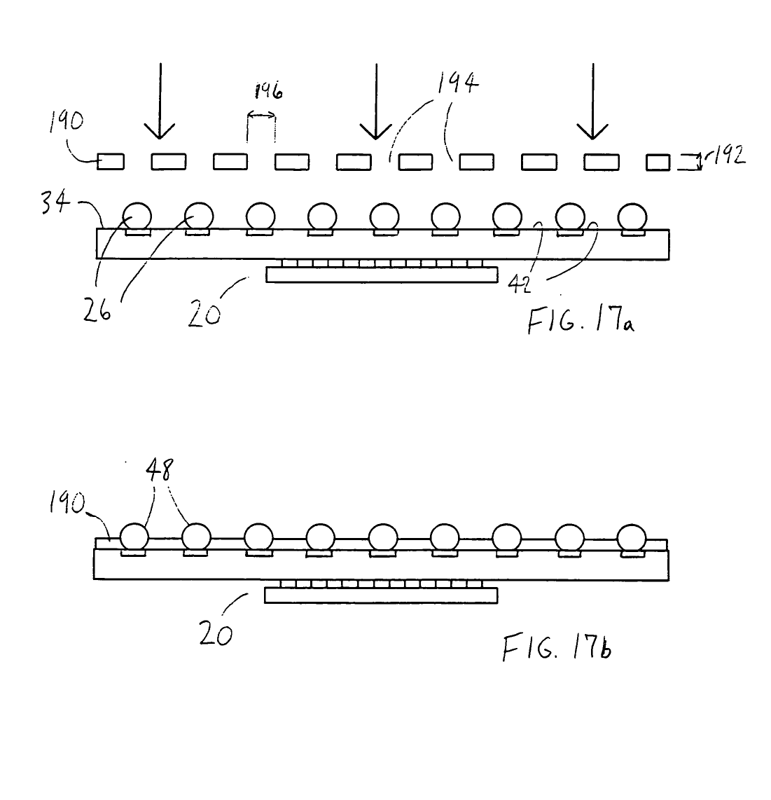

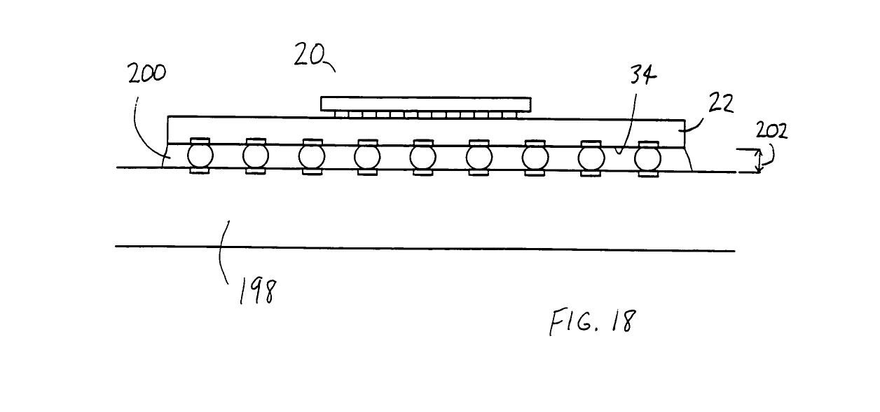

FIGS. 17a and 17b illustrate another method of forming the stress compensation layer on the semiconductor package using a cast film.

A cast film 190 of adhesive paste is positioned over the semiconductor package 20. The cast film 190 has a thickness 192, for example, of 0.37 mm and a plurality of holes 194 therein. Although only shown in cross section, it should be understood that the holes 194 are arranged on the cast film 190 in an array of rows and columns, similar to the rows and columns of the contact formations 26. Each hole 194 has a diameter 196, for example, of 0.5 mm. The cast film 190 is placed over the semiconductor package 20 so that each hole 194 lies directly over one of the solder balls 26.

The cast film 190 is then lowered onto the BGA surface 34 so that the solder balls 26 are pulled through the holes 194 and the cast film 190 covers the interstitial areas 42 of the BGA surface 34. Because of the thickness 192 of the cast film 190, the upper portions 48 of the solder balls 26 remain exposed. The resulting semiconductor package 20 is similar to the one shown in FIG. 9 with the stress compensation layer on the BGA surface 34.

FIG. 18 illustrates an alternative embodiment of the stress compensation layer formed on the BGA surface 34 of a semiconductor package 20. As shown, the semiconductor package 20 has been attached to a circuit board 198. In this embodiment, a stress compensation layer 200 has been formed to a thickness 202 such that there is no air space between the stress compensation layer 200 and the circuit board 198. This embodiment may be made by any of the methods described herein by simply increasing the amount of adhesive paste deposited onto the BGA surface 34.

An additional advantage of this embodiment is that because a greater portion of the solder balls is surrounded by the stress compensation layer, the stress reducing benefits are further increased.

Other materials may be used for forming the stress compensation layer such as various resins such as thermosets such as epoxies, polyimides, and thermoplastics such as polyolefins and urethanes, which may be cured by other means such as exposure to ultraviolet light and a “snap cure.” The snap cure involves exposure of the material to an aliphatic amine hardener. The materials used to form the stress compensation layer may, for example, have a modulus between 1 and 12 GPa, a CTE between 20 and 100 ppm, and a glass transition temperature between 50° C. and 175° C.

Another example is an epoxy resin with a room temperature viscosity of 45 Pa-s that also contains 65 weight percent of spherical silica filler to reduce the CTE and increase the modulus of the material, along with the elastomer, adhesion promoters, and imidazole based catalyst. After curing, the material has a glass transition temperature of 135° C., a modulus of about 9 GPa at room temperature, and a CTE of about 25 ppm below 135° C. and 90 ppm above 135° C.

A further example of the material is an epoxy resin with a room temperature viscosity of 31 Pa-s, which contains 70 weight percent of silica filler. After curing, the material has a glass transition temperature of 75° C., a modulus of about 11-12 GPA at room temperature, and a CTE of about 21 ppm below 75° C. and 90 ppm above 75° C.

Other embodiments of the invention may deposit the adhesive paste onto the BGA surface using a stencil with only one aperture for each array of solder balls. In embodiments utilizing the air space between the stress compensation layer and the circuit board, the thickness of the stress compensation layer may be anywhere between 5 to 80% of the height of the solder balls. Different types of solder may be used such as leaded, lead-free, indium tin, and tin bismuth. The solder balls may be made of other materials besides solder, such as copper, so long as an electrical connection is made to the integrated circuit. Other types of contact formations, besides solder balls, may be used on the bottom side of the package substrate such as posts and solder elements. Other configurations of microelectronic dies on the package substrate may be used, such as wire-bonded dies. If the dispensing tool is used to deposit the adhesive paste, the horizontal plate may more than one dispensing hole and the stress compensation layer may be localized. Other types of semiconductor packages may be used such as non-microprocessors including stacked packages and flash memory chips.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. An electronic assembly, comprising:
a circuit board;
a package substrate, having first and second sides, attached to the circuit board;
a plurality of contact formations on the first side of the package substrate interconnecting the circuit board and the package substrate;
a stress relief layer on the first side of the package substrate, a space being defined between the stress relief layer and the circuit board; and
a microelectronic die, having an integrated circuit formed therein, mounted on the second side of the package substrate.

2. The electronic assembly of claim 1, wherein each contact formation has a height and the stress relief layer has a thickness, the thickness of the stress relief layer being less than the height of the contact formations.

3. The electronic assembly of claim 1, wherein the stress relief layer is adjacent to a portion of the contact formations that corresponds to only a portion of the height of the contact formations.

4. The electronic assembly of claim 3, wherein the heights of the contact formations are between 0.2 and 1.5 mm.

5. The electronic assembly of claim 4, wherein the stress relief layer is polymeric.

6. The electronic assembly of claim 5, wherein the stress relief layer is an adhesive paste.

7. The electronic assembly of claim 6, wherein the thickness of the stress relief layer is between 0.15 and 0.225 mm.

8. The electronic assembly of claim 7, wherein the space is an air space.

9. The electronic assembly of claim 8, wherein the microelectronic die is a microprocessor.

10. An electronic assembly, comprising:
a package substrate having first and second sides;
a microelectronic die mounted to the first side of the package substrate;
a plurality of contact formations attached to the second side of the package substrate, each having a height; and
a stress relief layer on the second side of the package substrate, the layer having a thickness less than the height of the contact formations and being adjacent to only a portion of the height of the contact formations.

11. The electronic assembly of claim 10, wherein the microelectronic die is a microprocessor.

12. The electronic assembly of claim 11, wherein the contact formations are BGA solder balls.

13. The electronic assembly of claim 12, wherein the stress relief layer is polymeric.

14. An electronic assembly, comprising:
a circuit board;
a package substrate, having first and second sides, attached to the circuit board;
a plurality of contact formations on the first side of the package substrate interconnecting the circuit board and the package substrate;
a stress relief layer between the package substrate and the circuit board; and
a microprocessor mounted on the second side of the package substrate.

15. The electronic assembly of claim 14, wherein the circuit board is a motherboard.

16. The electronic assembly of claim 15, wherein the stress relief layer is adjacent to the contact formations.

17. A method of constructing an electronic assembly, comprising:
depositing a stress relief layer on a side of a package substrate, the side having a plurality of contacts formations thereon; and
attaching the contact formations to a circuit board, a space being defined between the stress relief layer and the circuit board.

18. The method of claim 17, wherein a microelectronic die is mounted on an opposing side of the package substrate.

19. The method of claim 18, wherein the contacts have a height and the stress relief layer has a thickness, the thickness of the stress relief layer being less than the height of the contact formations.

20. The method of claim 19, wherein the stress relief layer is adjacent to a portion of the contact formations that corresponds to only a portion of the height of the contact formations.

21. The method of claim 20, wherein the stress relief layer is polymeric.

22. The method of claim 21, wherein the stress relief layer is only deposited onto selected portions of the side of the package substrate.

23. The method of claim 21, wherein the stress relief layer flows onto the package substrate.

24. The method of claim 23, wherein the stress relief layer is first deposited onto a central portion of the side of the package substrate.

25. The method of claim 21, wherein the stress relief layer is extruded onto the side of the side of the package substrate.

26. The method of claim 21, wherein the stress relief layer is a cast film, having a plurality of holes therein, and said depositing is placing the cast film on the side of the package substrate so that the contact formations extend through the holes.

27. A method comprising:
placing a plurality of semiconductor packages on a support, the semiconductor packages each having a package substrate with a first side having a microelectronic die mounted thereon and a second side with a plurality of contact formations connected thereto, the contact formations having a height;
suspending a stencil over the semiconductor packages, the stencil having a plurality of holes; and
flowing a paste through the holes of the stencil to form a stress relief layer on the second side of the package substrate of each semiconductor package, the stress relief layer having a thickness, the thickness being less than the height of the contact formations.

28. The method of claim 27, further comprising placing the semiconductor packages onto circuit boards, the contact formations interconnecting the package substrates and the circuit board, a space being defined between the circuit board and the second side of the package substrate.

29. The method of claim 28, wherein the stress relief layer is adjacent to a portion of the contact formations that corresponds to only a portion of the height of the contact formations.

30. The method of claim 29, wherein the second sides of the package substrates face the stencil.
